(19) United States
(12) Patent Application Publication
(10) Pub. No.: US 2021/0054501 A1
(43) Pub. Date: Feb. 25, 2021

(54) FILM FORMING METHOD AND FILM FORMING APPARATUS

(71) Applicant: TOKYO ELECTRON LIMITED, Tokyo (JP)

(72) Inventors: Hideomi HANE, Nirasaki City (JP); Takeshi OYAMA, Nirasaki City (JP); Shimon OTSUKI, Oshu City (JP); Ren MUKOUYAMA, Oshu City (JP); Noriaki FUKIAGE, Nirasaki City (JP); Jun OGAWA, Nirasaki City (JP)

(21) Appl. No.: 16/989,103

(22) Filed: Aug. 10, 2020

(30) Foreign Application Priority Data
Aug. 19, 2019 (JP) 2019-149953

(51) Int. Cl. C23C 16/34; H05H 1/24; C23C 16/455; C23C 16/52; H01L 21/02

(52) U.S. Cl. CPC C23C 16/345; H05H 1/24; C23C 16/45536; H01L 21/02211; H01L 21/02175; H01L 21/0217; C23C 16/52

(57) ABSTRACT

A film forming method of forming a silicon nitride film on a substrate, which includes a first film and a second film having different incubation times when a source gas containing silicon and a first nitriding gas for nitriding the silicon are supplied, includes: supplying a plasmarized hydrogen gas to the substrate; supplying a processing gas formed of silicon halide to the substrate; forming a thin layer of silicon covering the first film and the second film by alternately and repeatedly performing the supplying the plasmarized hydrogen gas and the supplying the processing gas; forming a thin layer of silicon nitride by supplying a second nitriding gas for nitriding the thin layer of silicon to the substrate; and forming the silicon nitride film on the thin layer of the silicon nitride by supplying the source gas and the first nitriding gas to the substrate.

### CROSS-REFERENCE TO RELATED APPLICATION(S)

Tis application is based upon and claims the benefit of priority from Japanese Patent Application No. 2019-149953, filed on Aug. 19, 2019, the entire contents of which are incorporated herein by reference.

### TECHNICAL FIELD

The present disclosure relates to a film forming method and a film forming apparatus.

### BACKGROUND

In a semiconductor manufacturing process, a film forming process of forming a silicon nitride (SiN) film on a semiconductor wafer (hereinafter referred to as a “wafer”) as a substrate may be performed. There may be a case where films having different incubation times, which will be described later, are exposed on the surface of the wafer. Even in that case, it is required to form the SiN film to have a highly uniform film thickness in each in-plane portion of the wafer. Patent Document 1 discloses supplying and adsorbing ammonia (NH₃) onto a wafer having a silicon (Si) film and a silicon oxide (SiO₂) film exposed on the surface thereof, and then nitriding the films by exposing the wafer to plasma of an argon (Ar) gas. Patent Document 1 further discloses that, after nitriding the films, a silicon-containing source gas and a plasmarized NH₃ gas are alternately supplied to the wafer to form a silicon nitride (SiN) film.

### PRIOR ART DOCUMENT

### Patent Document

Patent Document 1: Japanese laid-open publication No. 2017-175106

### SUMMARY

A film forming method according to the present disclosure is a method of forming a silicon nitride film on a substrate including a first film and a second film formed on a surface of the substrate, wherein the first film and the second film have different required incubation times until growth of the silicon nitride film starts when a source gas containing silicon and a first nitriding gas for nitriding the silicon are supplied. The method includes: supplying a plasmarized hydrogen gas to the substrate; supplying a processing gas formed of silicon halide to the substrate; forming a thin layer of silicon covering the first film and the second film by alternately and repeatedly performing the supplying the plasmarized hydrogen gas and the supplying the processing gas; forming a thin layer of silicon nitride by supplying a second nitriding gas for nitriding the thin layer of silicon to the substrate; and forming the silicon nitride film on the thin layer of the silicon nitride by supplying the source gas and the first nitriding gas to the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical cross-sectional view of a film forming apparatus according to an embodiment of the present disclosure.

FIG. 2 is a horizontal cross-sectional view of the film forming apparatus.

FIG. 3 is a vertical cross-sectional view of a shower head.

FIG. 4 is a bottom view of the shower head provided in the film forming apparatus.

FIG. 5 is a vertical cross-sectional view of a wafer processed by the film forming apparatus.

FIG. 6 is a vertical cross-sectional view of the wafer.

FIG. 7 is a vertical cross-sectional view of the wafer.

FIG. 8 is a vertical cross-sectional view of the wafer.

FIG. 9 is a vertical cross-sectional view of the wafer.

FIG. 10 is a flowchart illustrating an embodiment of a film forming method performed by the film forming apparatus.

FIGS. 11A to 11D are schematic views illustrating changes in a surface of the wafer.

FIG. 12 is a graph indicating a result of an evaluation test.

FIG. 13 is a graph indicating a result of an evaluation test.

FIG. 14 is a graph indicating a result of an evaluation test.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

An outline of a film forming method according to an embodiment of the present disclosure will be described first. In this embodiment, a process of forming a SiN film is performed on a wafer B having a silicon (Si) film, a silicon oxide (SiO₂) film, and a tungsten (W) film as a metal film, exposed on the surface thereof. Since tungsten (W) is easily oxidized, the process is performed in a state in which oxygen atoms are present on the surface of the W film.

Here, an incubation time of a SiN film will be described. The incubation time of the SiN film is a time required, when forming a SiN film by supplying a silicon-containing source gas and a nitriding gas for nitriding silicon, until formation of the SiN film starts after starting the supply of one of the above-mentioned gases. More specifically, by supplying the source gas and the nitriding gas, a plurality of island-shaped SiN nuclei are formed in a base film of the SiN film. As the nuclei of SiN spread and grow along the surface of the base film, the nuclei of SiN come into contact with one another to form a thin layer. Then, the thin layer grows as the SiN film (a film thickness increases). Accordingly, a timing at which the growth of the film is started is the timing at which the SiN thin layer is formed. The time required for the formation and growth of the nuclei varies depending on a type of a film, which serves as the base film of the SiN film and is in contact with the SiN film.

The expression “respective films have different SiN film incubation times” means that, in forming SiN films in contact with the respective films by supplying a source gas and a nitriding gas to the respective films under the same condition, times from the start of supplying the gases to the formation of the above-mentioned thin layer differ from one another. Additionally, it means that as a result of comparison without performing processes other than adsorbing the source gas and nitriding silicon in the source gas by using the nitriding gas, the times until the thin layers are formed differ from one another. That is to say, the comparison is performed without performing a reduction process or a modification process using hydrogen plasma, which are processes performed in the present embodiment. In addition, the nitriding gas referred to herein also includes a plasmarized nitriding gas in addition to a non-plasmarized nitriding gas.

When the source gas and the nitriding gas are supplied to respective base films having different incubation times as described above, due to the difference in the incubation times, variations may occur in the thicknesses of SiN films formed to be in contact with the respective base films. A W film, a SiO₂ film, and a Si film formed on the wafer B of the present embodiment have different SiN film incubation times. Specifically, when the W film and the SiO₂ film are referred to as a first film and the Si film is referred to as a second film, the incubation time of the first film is longer than the incubation time of the second film.

Therefore, in the present embodiment, a preprocessing is performed to suppress influence of the difference in the incubation times and to make the thicknesses of the SiN films uniform. As the preprocessing, first, a hexachlorodisilane (Si₂Cl₆) gas and a plasmarized hydrogen (H₂) gas are alternately and repeatedly supplied to the wafer B to form a thin Si layer covering the above-mentioned films, and the thin Si layer is nitrided to form a thin SiN layer. For reasons to be described later, the nitriding process is performed by supplying a plasmarized NH₃ gas (second nitriding gas) to the wafer B.

In addition, after performing the preprocessing, an atomic layer deposition (ALD) process using a Si₂Cl_{f} gas and a plasmarized NH₃ gas (first nitriding gas) is performed to form a SiN film on the thin SiN layer. Hereinafter, hexachlorodisilane (Si₂Cl₆) may also be referred to as HCD. As described above, the HCD gas is a processing gas for performing the preprocessing, and is also a source gas for forming the SiN film. Further, in the present specification, silicon nitride is referred to as SiN regardless of a stoichiometric ratio thereof. Accordingly, the expression “SiN” includes, for example, Si:N₄. Furthermore, the base film includes the wafer B itself, in addition to the film formed on the wafer B. Accordingly, for example, the above-mentioned Si film may be a film formed on a silicon wafer or the silicon wafer itself.

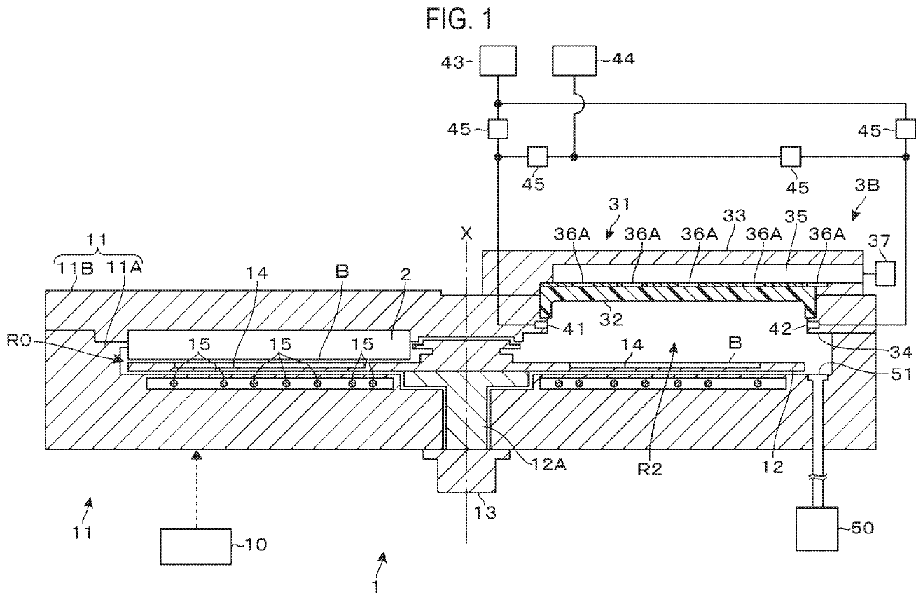

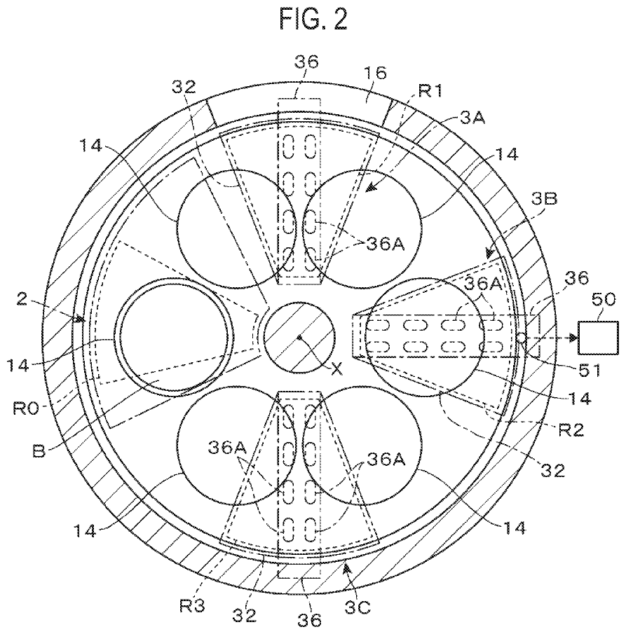

Hereinafter, a film forming apparatus 1, which is an embodiment of an apparatus for carrying out the above-described film forming method, will be described with reference to the vertical cross-sectional view of FIG. 1 and the horizontal cross-sectional plan view of FIG. 2. The film forming apparatus 1 includes a flat and substantially circular vacuum container (processing container) 11. The vacuum container 11 includes a container body 11A constituting aside wall and a bottom, and a ceiling plate 11B. In the drawings, reference numeral 12 denotes a circular rotary table horizontally provided in the vacuum container 11. In the drawings, reference numeral 12A is a support that supports a center portion of a rear surface of the rotary table 12. In the drawings, reference numeral 13 denotes a rotary mechanism that rotates the rotary table 12 clockwise in a plan view, along a circumferential direction of the rotary table 12 via the support 12A. In addition, reference symbol X in the drawings represents a rotary axis of the rotary table 12.

Six circular recesses 14 are formed in a top surface of the rotary table 12 along the circumferential direction (rotation direction) of the rotary table 12, and the wafer B is accommodated in each recess 14. That is to say, each wafer B is mounted on the rotary table 12 so as to rotate by the rotation of the rotary table 12. In addition, reference numeral 15 in FIG. 1 denotes heaters. The heaters are concentrically provided at a bottom portion of the vacuum container 11 to heat the wafers B placed on the rotary table 12. In FIG. 2, reference numeral 16 denotes a transfer port of the wafer B, which is opened in the side wall of the vacuum container 11 and is configured to be capable of being opened and closed by a gate valve (not illustrated). The wafer B is delivered between the outside of the vacuum container 11 and the inside of each recess 14 through the transfer port 16 by a substrate transfer mechanism (not illustrated).

Above the rotary table 12, a shower head 2, a plasma forming unit 3A, a plasma forming unit 3B, and a plasma forming unit 3C are provided in this order along the rotation direction of the rotary table 12 towards a downstream side in the rotation direction. The shower head 2, which is a first gas supplier, supplies an HCD gas used for the SiN film formation and the preprocessing to the wafer B. The plasma forming units 3A to 3C, which are a second gas supplier, are units for plasmarizing a plasma forming gas supplied onto the rotary table 12 to perform a plasma processing on the wafers B. Each of the plasma forming units 3A to 3C is configured to independently form plasma of a H₂ gas alone and plasma of a NH₃ gas and a H₂ gas. In addition, below the outside of the rotary table 12 in the vacuum container 11 and outside the second plasma forming unit 3B, an exhaust port 51 for exhausting plasma forming gases supplied by the plasma forming units 3A to 3C is opened. A vacuum exhaust mechanism 50 is connected to the exhaust port 51.

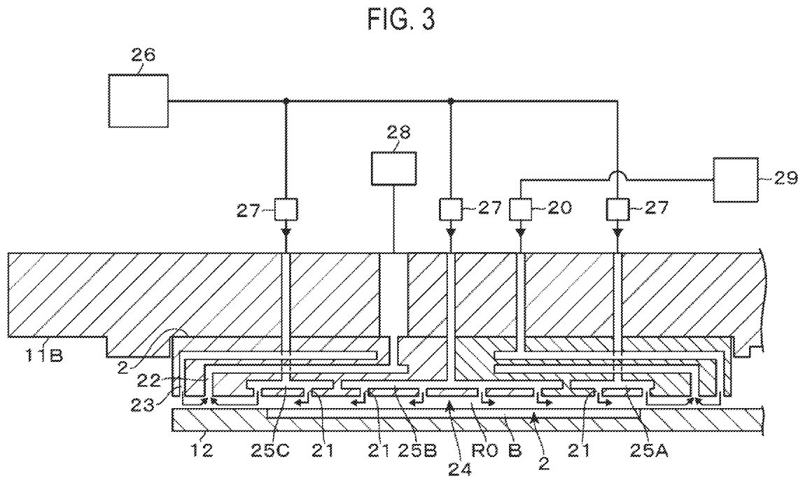

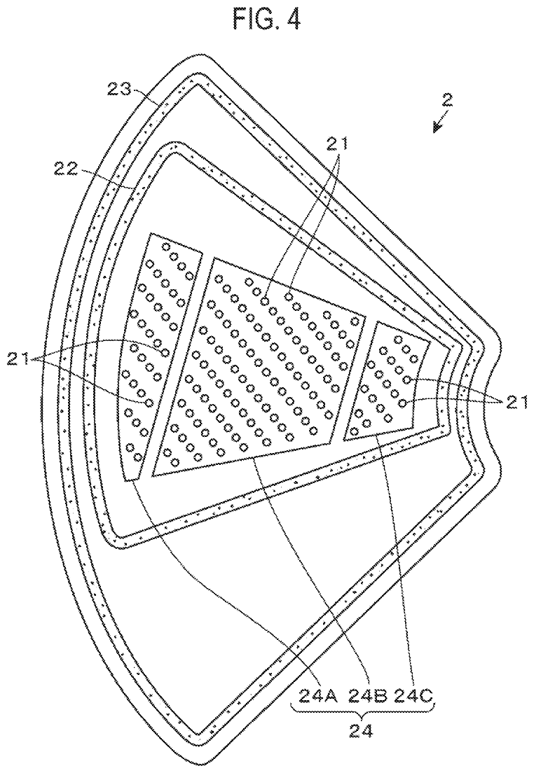

The shower head 2, which is a processing gas supplier and a source gas supplier, will be described with reference to a vertical cross-sectional view of FIG. 3 and a bottom view of FIG. 4. The shower head 2 is formed in a fan shape in a plan view, which is widened in the circumferential direction of the rotary table 12 from a center side towards a peripheral side of the rotary table 12, and a bottom surface of the shower head 2 is close to and faces the top surface of the rotary table 12. In the bottom surface of the shower head 2, gas ejection ports 21, an exhaust port 22, and a purge gas ejection port 23 are opened. To facilitate identification, the exhaust port 22 and the purge gas ejection port 23 are indicated by a large number of dots in FIG. 4. The gas ejection ports 21 are arranged in a fan-shaped region 24 disposed inward of a peripheral edge portion of the bottom surface of the shower head 2. The gas ejection ports 21 are opened to eject an HCD gas downwards in the form of a shower during the rotation of the rotary table 12 and supply the HCD gas to an entire surface of each wafer B.

The fan-shaped region 24 is divided into three zones 24A, 24B, and 24C from the center side of the rotary table 12 towards the peripheral side of the rotary table 12. The shower head 2 is provided with gas flow paths 25A, 25B, and 25C partitioned from one another such that the HCD gas can be independently supplied to the gas ejection ports 21 provided in respective zones 24A, 24B, and 24C. The upstream side of each of the gas flow paths 25A, 25B, 25C is connected to an HCD gas source 26 via a pipe, and a gas supply device 27 including a valve and amass flow controller is provided in each pipe. By the gas supply device 27, supply and cutoff of the HCD to the downstream side of the pipe and flow rate adjustment of the HCD are performed. In addition, each gas supply device (described later) other than the gas supply device 27 is also configured in the same manner as the gas supply device 27, and performs supply and cut off of a gas to the downstream side and flow rate adjustment of the gas.

The exhaust port 22 and the purge gas ejection port 23 are annularly opened in the peripheral edge portion of the bottom surface of the shower head 2 so as to face the top surface of the rotary table 12 while surrounding the fan-shaped region 24. The purge gas ejection port 23 is located outward of the purge gas ejection port so as to surround the exhaust port 22. A region inward of the exhaust port 22 on the rotary table 12 forms an adsorption region R0 in which HCD is adsorbed to the wafer B. The purge gas ejection port 23 ejects, for example, an Ar (argon) gas as a purge gas onto the rotary table 12.

During the ejection of the HCD gas from the gas ejection ports 21, exhaust from the exhaust port 22 and ejection of the purge gas from the purge gas ejection port 23 are both performed. Thus, as illustrated by arrows in FIG. 3, the source gas and the purge gas ejected towards the rotary table 12 are directed to the exhaust port 22 above the top surface of the rotary table 12 and are exhausted from the exhaust port 22. By performing the ejection and exhaust of the purge gas as described above, the atmosphere in the adsorption region R0, which is a first region, is separated from the external atmosphere, and the source gas can be supplied to the adsorption region R0 in a restricted manner. That is to say, the HCD gas supplied to the adsorption region R0 is suppressed from being mixed with each gas supplied to the outside of the adsorption region R0 by the plasma forming units 3A to 3C as described later, and thus the film forming process using an ALD method can be performed. Reference numeral 28 in FIG. 3 denotes an exhaust mechanism for performing exhaust from the exhaust port 22 via a pipe. Reference numeral 29 in FIG. 3 denotes a source of an Ar gas, which is a purge gas, and supplies the Ar gas to the purge gas ejection port 23 via a pipe. A gas supply device 20 is provided in the pipe.

Next, the plasma forming unit 3B will be described with reference to FIGS. 1 and 2. The plasma forming unit 3B supplies microwaves to the plasma forming gas (a H₂ gas or a mixed gas of a H₂ gas and a NH₃ gas) ejected to below the plasma forming unit 3B so as to generate plasma on the rotary table 12. The plasma forming unit 3B includes an antenna 31 for supplying the microwaves, and the antenna 31 includes a dielectric plate 32 and a waveguide 33 formed of metal.

The dielectric plate 32 is formed in a substantially fan shape that is widened from the center side of rotary table 12 towards the peripheral side in a plan view. The ceiling plate 11B of the vacuum container 11 has a substantially fan-shaped through hole corresponding to the shape of the dielectric plate 32, and the inner peripheral surface of a lower end portion of the through hole slightly protrudes towards the center of the through hole to form a support 34. The dielectric plate 32 closes the fan-shaped through-hole from above and faces the rotary table 12, and a peripheral edge portion of the dielectric plate 32 is supported on the support 34.

The waveguide 33 is provided on the dielectric plate 32, and includes an inner space 35 extending above the ceiling plate 11B. In the drawings, reference numeral 36 denotes a slot plate constituting a bottom side of the waveguide 33. The slot plate 36 has a plurality of slot holes 36A formed therein and is provided to be in contact with the dielectric plate 32. An end portion of the waveguide 33 on the center side of the rotary table 12 is closed, and a microwave generator 37 configured to supply microwaves of, for example, about 2.35 GHz to the waveguide 33 is connected to an end portion of the waveguide 33 on the peripheral side of the rotary table 12. The microwaves pass through the slot holes 36A in the slot plate 36, reach the dielectric plate 32, and are supplied to the plasma forming gas supplied below the dielectric plate 32. Thus, plasma is formed below the dielectric plate 32 in a restricted manner, and the wafer B is processed. As described above, a region below the dielectric plate 32 is configured as a plasma forming region, and is indicated as R2.

Further, the plasma forming unit 3B includes a gas ejection hole 41 and a gas ejection hole 42, which are formed in the support 34. The gas ejection hole 41 ejects the plasma forming gas from the center side of the rotary table 12 towards the outer peripheral side thereof, and the gas ejection hole 42 ejects the plasma forming gas from the outer peripheral side of the rotary table 12 towards the center side thereof. Each of the gas ejection hole 41 and the gas ejection hole 42 is connected to a H₂ gas source 43 and a NH₃ gas source 44 via a piping system including gas supply devices 45. In addition, the plasma forming units 3A and 3C are configured similarly to the plasma forming unit 3B, and regions corresponding to the plasma forming region R2 in the plasma forming units 3A and 3C are indicated as plasma forming regions R1 and R3, respectively. The plasma forming regions R1 to R3 area second region, and the plasma forming units 3A to 3C form a hydrogen gas supplier and a nitriding gas supplier.

As illustrated in FIG. 1, the film forming apparatus 1 is provided with a controller 10 configured by a computer, and the controller 10 stores a program. In this program, a group of steps is programmed such that control signals are transmitted to each part of the film forming apparatus 1 so as to control operation of each part, whereby the above-described preprocessing and the SiN film forming process are executed. Specifically, for example, the rotation number of the rotary table 12 rotated by the rotary mechanism 13, operation of each gas supply device, a gas exhaust amount from each of the exhaust mechanisms 28 and 50, supply and cut off of microwaves from the microwave generator 37 to the antenna 31, and power supply to the heater 15 are controlled by the program. The control of power supply to the heater 15 is a control of a temperature of the wafers B, and the control of the gas exhaust amount from the exhaust mechanism 50 is a control of a pressure in the vacuum container 11. The program is stored in a non-transitory storage medium such as a hard disc, a compact disc, a DVD, or a memory card, and is installed in the controller 10.

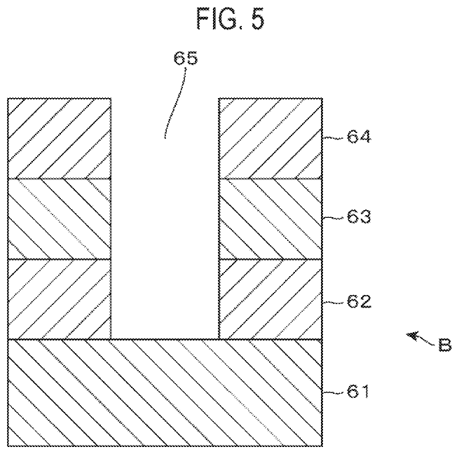

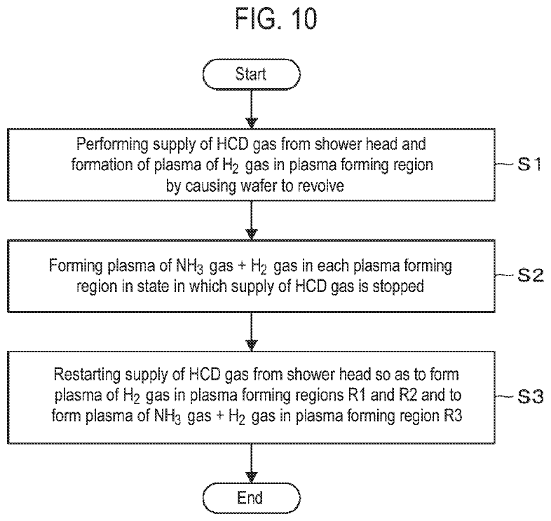

Hereinafter, the preprocessing and the SiN film forming process performed by the film forming apparatus 1 will be described with reference to FIGS. 5 to 9, which are vertical cross-sectional views of the wafer B, and FIG. 10, which is a flowchart of operation of the film forming apparatus 1. FIG. 5 illustrates an exemplary wafer B transferred to the film forming apparatus 1. The wafer B has a stacked structure in which a Si film 61, a SiO₂ film 62, a W film 63, and a SiO₂ film 64 are stacked upwards in this order. A recess 65 is formed in the stacked structure. A side surface of the recess 65 is formed of the SiO₂ film 62, the W film 63, and the SiO₂ film 64, and a bottom surface of the recess 65 is formed of the Si film 61. Accordingly, as described above, the Si film, the SiO₂ film, and the W film are exposed on the surface of the wafer B.

Six wafers B illustrated in FIG. 5 are placed in the recesses 14 in the rotary table 12. Then, the gate valve provided at the transfer port 16 in the vacuum container 11 is closed to hermetically seal the interior of the vacuum container 11, and the wafers B are heated to, for example, 200 degrees C. to 600 degrees C., more specifically, for example, 550 degrees C. by the heaters 15. Then, by exhausting from the exhaust port 51, the interior of the vacuum container 11 is turned into a vacuum atmosphere of, for example, 53.3 Pa to 666.5 Pa, and the rotary table 12 is rotated at, for example, 3 rpm to 60 rpm, whereby each wafer B rotates.

By the plasma forming units 3A to 3C, the H₂ gas and the microwaves are supplied to the plasma forming regions R1 to R3 respectively, and plasma of the H₂ gas is formed in each of the plasma forming regions R1 to R3. Meanwhile, in the shower head 2, the HCD gas is ejected from the gas ejection ports 21 and the Ar gas is ejected from the purge gas ejection port 23, and exhaust is performed from the exhaust port 22 (step S1 in FIG. 10). By operating the shower head 2 and the plasma forming units 3A to 3C as described above, supplying the HCD gas and supplying the plasmarized H₂ gas are alternately and repeatedly performed for each rotating wafer B.

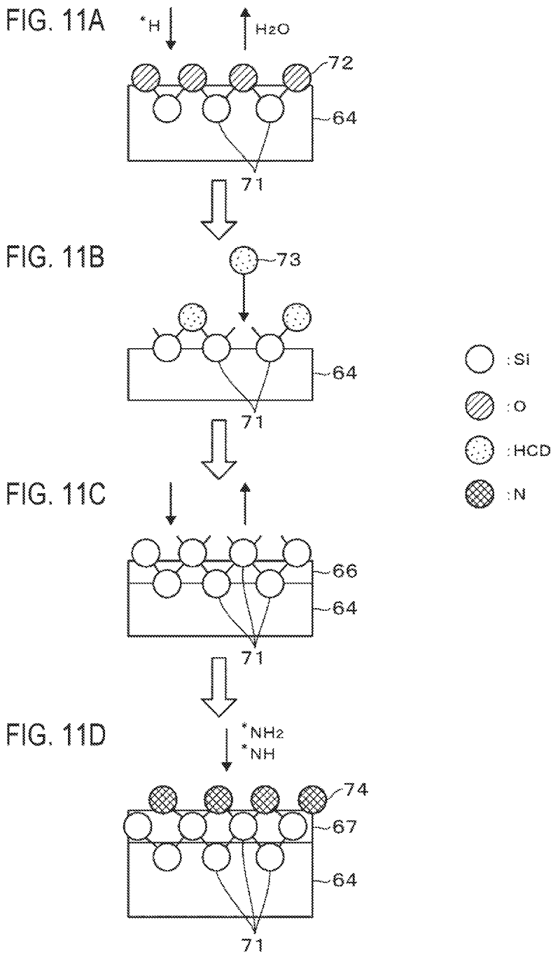

FIGS. 11A to 11D schematically illustrate reactions that may occur on the surface of a SiO₂ film 64 when the preprocessing is performed as described above. In the drawings, reference numeral 71 denotes Si atoms, reference numeral 72 denotes O atoms, and reference numeral 73 denotes HCD molecules. The wafer B is located in the plasma forming regions R to R3, and active species (e.g., H radicals) of the H₂ gas forming plasma react with the O atoms 72 on the surface of the SiO₂ film 64. Thus, the O atoms 72 become H₂O and are desorbed from the SiO₂ film 64, and the surface of the SiO₂ film 64 is reduced (see FIG. 11A). As a result, the surface of the SiO₂ film 64 enters a state in which a relatively large number of Si atoms 71 are present.

Subsequently, the wafer B is located in the adsorption region R0, and the HCD molecules 73 are supplied to the reduced surface of the SiO₂ film 64 (see FIG. 11B). It is considered that by being reduced by H radicals as described above, the surface of the SiO₂ film 64 is activated and enters a state in which the supplied HCD molecules 73 are easily adsorbed. Thus, the adsorption proceeds efficiently. When the wafer B is located again in the plasma forming regions R1 to R3 in a state in which the HCD molecules 73 are adsorbed thereto as described above, the active species of the H₂ gas react with chlorine (Cl) atoms contained in the adsorbed HCD molecules 73. As a result, the Cl atoms of the HCD molecules 73 become HCl (hydrochloric acid) and are desorbed from the SiO₂ film 64, and Si atoms 71 generated from the HCD molecules 73 are adsorbed on the surface of the SiO₂ film 64.

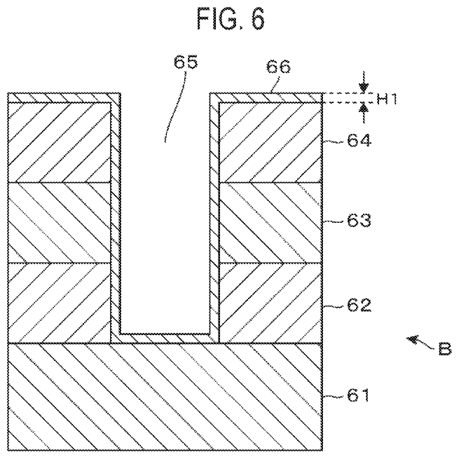

Although the changes in the surface of the SiO₂ film 64 has been described, similarly to the SiO₂ film 64, O atoms 72 on the surface of the SiO₂ film 62 are also removed and Si atoms 71 are adsorbed to the surface of the SiO₂ film 62. In addition, since the surface of the Si film 61 is composed of Si atoms 71, the HCD molecules 73 are easily adsorbed thereto. Thus, similarly to the SiO₂ films 62 and 64, Si atoms 71 contained in the HCD molecules 73 are adsorbed to the Si film 61. Similar to the SiO₂ films 62 and 64, the W film 63 is presumed to have a relatively large amount of HCD molecules 73 adsorbed to the surface of the W film 63 by the reduction and activation of the surface of the W film 63 by H radicals. That is to say, the Si atoms 71 are efficiently adsorbed on the surface of each of the Si film 61, the SiO₂ films 62 and 64, and the W film 63. When the wafer B continues to rotate and the wafer B repeatedly moves between the adsorption region R0 and the plasma forming regions R1 to R3, the adsorption of the Si atoms 71 progresses, and thus a thin layer 66 of Si is formed to cover the entire surface of the wafer B (see FIGS. 6 and 11C).

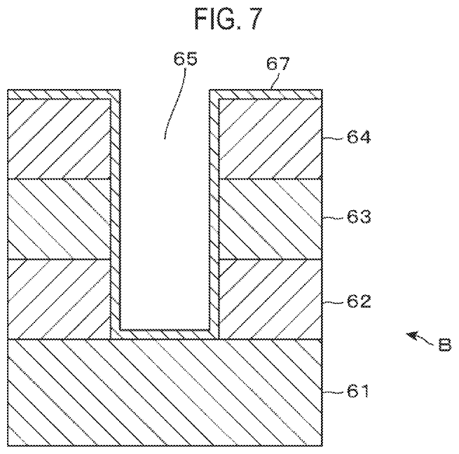

After the supply of the HCD gas from the shower head 2 and the formation of the H₂ plasma by the plasma forming units 3A to 3C are started, when the rotary table 12 is rotated a preset number of times, for example, 30 times, the supply of the HCD gas from the shower head 2 is stopped. While the supply of the HCD gas is stopped as described above, the H₂ gas and the NH₃ gas are supplied to the plasma forming regions R1 to R3, and plasma of these gases is formed (step S2 in FIG. 10). Then, the rotation of the wafer B continues, and each wafer B repeatedly passes through the plasma forming regions R1 to R3. Thus, active species (e.g., NH₂ radicals and NH radicals) of the NH₃ gas forming the plasma react with the thin layer 66 of Si, and the thin layer 66 is nitrided to form a thin layer 67 of SiN (see FIG. 7 and FIG. 11D). In addition, reference numeral 74 in FIG. 11D denotes nitrogen atoms.

When the rotary table 12 is rotated a preset number of times from the start of the plasma formation of the H₂ gas and the NH₃ gas, the supply of the HCD gas from the shower head 2 to the adsorption region R0 restarts. Further, in the plasma forming regions R1 and R2, while the supply of the NH₃ gas is stopped, the H₂ gas is continuously supplied and the plasma of the H₂ gas is formed. In the plasma forming region R3, the H₂ gas and the NH₃ gas are continuously supplied, and the plasma of these gases is formed (step S3 in FIG. 10).

Then, the wafer B continues to rotate, and the supply of the HCD gas in the adsorption region R0, the supply of the plasmarized H₂ gas in the plasma forming regions R1 and R2, and the supply of the plasmarized H₂ gas and NH₃ gas in the plasma forming region R3 are sequentially repeated. The Si in the HCD gas adsorbed on the wafer B in the adsorption region R0 is nitrided in the plasma forming region R3 to form SiN. Then, in the plasma forming regions R1 and R2, the deposited SiN is modified by the plasma of the H₂ gas. Specifically, H is bonded to dangling bonds in SiN and Cl is removed from the deposited SiN. Thus, the SiN becomes dense and has a low content of impurities.

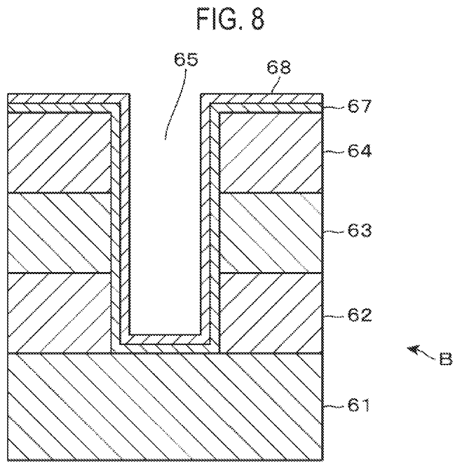

The formation and growth of SiN nuclei occur as described above, and since the base is the thin layer 67 formed of SiN, which is the same material as that of the nuclei, the nuclei are formed and grown relatively quickly. In addition, the thin layer 67 of SiN is formed commonly on the Si film 61, the SiO₂ films 62 and 64, and the W film 63, and the surface conditions of these films are made uniform. Therefore, the formation and growth of the nuclei occur similarly on the Si film 61, the SiO₂ films 62 and 64, and the W film 63, and a thin layer of SiN (a SiN film 68) is formed. That is, the SiN film 68 is formed on the Si film 61, the SiO₂ films 62 and 64, and the W film 63, as if the incubation times of the Si film 61, the SiO₂ films 62 and 64, and the W film 63 are uniform (see FIG. 8).

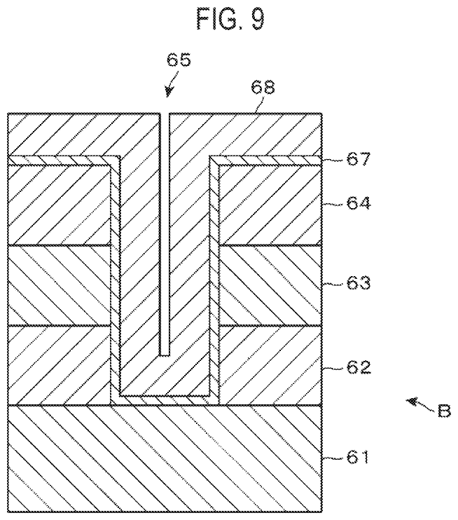

As the rotation of the wafer B continues, the thickness of the SiN film 68 increases, and modification of the SiN film 68 proceeds. Since the SiN film 68 starts to be formed on the Si film 61, the SiO₂ films 62 and 64, and the W film 63 at the same timing as described above, the SiN film 68 grows with a highly uniform thickness among these films. After the supply of the HCD gas and the plasma formation of the gases in the plasma forming regions R1 to R3 in step S3 are started, when the rotary table 12 is rotated a preset number of times to form the SiN film 68 having a desired thickness, a process of forming the SiN film 68 is completed (see FIG. 9). That is, the supply of each of the gases, the supply of the microwaves, and the rotation of the rotary table 12 are stopped, and the film forming process is terminated. Thereafter, the wafer B is unloaded from the vacuum container 11 by the substrate transfer mechanism.

As described above, according to the process using the film forming apparatus 1, the influence of the difference in the incubation times of the SiN film 68 among the Si film 61, the SiO₂ films 62 and 64, and the W film 63 is suppressed. Thus, it is possible to make the timing at which film formation is started uniform. As a result, it is possible to form the SiN film 68 so as to have a highly uniform thickness on each of the films.

In addition, since the thin layer 67 of SiN generated from the thin layer 66 of Si and the SiN film 68 are formed by different methods, the thin layer 67 of SiN and the SiN film 68 may be different from each other in terms of film quality. Thus, when the thickness of the thin layer 66 of Si becomes too large, the characteristics of a product manufactured from the wafer B may be affected. Therefore, in some embodiments, a thickness H1 of the thin layer 66 of Si (see FIG. 6) when the supply of the HCD gas is stopped in the above-described process may be small, for example, 1 nm or less.

The nitridation of the thin layer 66 of Si formed in step S1 described above may be performed using plasma of a N₂ gas. However, in order to make the film quality of the thin layer 67 of SiN generated from the thin layer 66 equal to the film quality of the SiN film 68, the thin layer 66 of Si may be nitrided using plasma of a NH₃ gas as described above. In addition, the thin layer 66 of Si may be nitrided by supplying a non-plasmarized N₂ gas or NH₃ gas. As described above, the nitridation of the thin layer 66 of Si is not limited to using plasma of a NH₃ gas.

Further, the formation of the SiN film 68 after the formation of the thin layer 67 of SiN is not limited to being performed using an ALD method, and may be performed using a chemical vapor deposition (CVD) method. In forming the SiN film 68, it is sufficient to nitride silicon in the source gas. Thus, the formation of the SiN film 68 is not limited to using the plasmarized NH₃ gas, and, for example, a non-plasmarized NH₃ gas may be used.

In addition, the formation of the thin layer 66 of Si is not limited to using an HCD gas, and a gas composed of silicon chloride such as a dichlorosilane (DCS) gas may be used. Alternatively, the thin layer 66 of Si may be formed using a silicon halide gas composed of halogen other than chlorine, such as iodine. However, as described above, an HCD gas may be used in some embodiments, because a large amount of Si is contained in one molecule and thus a large amount of Si can be efficiently adsorbed to the wafer B. Further, in the exemplary process described above, the same HCD gas is used as the processing gas for forming the thin layer 66 of Si and as the silicon-containing source gas for forming the SiN film 68. However, the processing gas and the source gas may be different from each other. For example, an HCD gas may be used as the processing gas and a DCS gas may be used as the source gas.

In the exemplary process described above, a SiN film is formed on the W film 63 as a metal film. However, the metal film is not limited to the W film 63, and the present disclosure is effective even when forming the SiN film 68 on a metal film formed of, for example, titanium (Ti) or nickel (Ni). That is, the metal film serving as the base of the SiN film is not limited to the W film. It should be understood that the embodiments disclosed herein are examples in all respects and are not restrictive. The above-described embodiments may be omitted, replaced, or modified in various forms without departing from the scope and spirit of the appended claims.

Hereinafter, evaluation tests performed in relation to the present technology will be described.

### (Evaluation Test 1)

As Evaluation Test 1, plural sheets of wafers, each of which is formed of Si and has a bare surface (hereinafter, referred to as bare wafers), and plural sheets of wafers, each of which is formed of Si and has a SiO₂ film formed on the surface thereof (hereinafter, referred to as SiO₂ wafers) were prepared. Then, a series of processes (the preprocessing and the process of forming the SiN film 68) including steps S1 to S3 described in the embodiments described above were performed on each of the bare wafers and the SiO₂ wafers. A processing time for forming the SiN film 68 in step S3 in the series of processes was set to 180 seconds or 360 seconds. After completion of the series of processes, thicknesses of the formed SiN films 68 were measured.

In addition, as Comparative Test 1, instead of performing the process of step S1 described above, a process of nitriding the surfaces of the bare wafers and the SiO₂ wafers was performed by supplying a N₂ gas to the plasma forming regions R1 to R3 and plasmarizing the N₂ gas. After the nitriding process, the above-described step S2 and step S3 were performed on each of the wafers. However, instead of an HCD gas, a DCS gas was used as the source gas in step S3. Except for the above-described differences, the processes of Comparative Test 1 were the same as those of Evaluation Test 1.

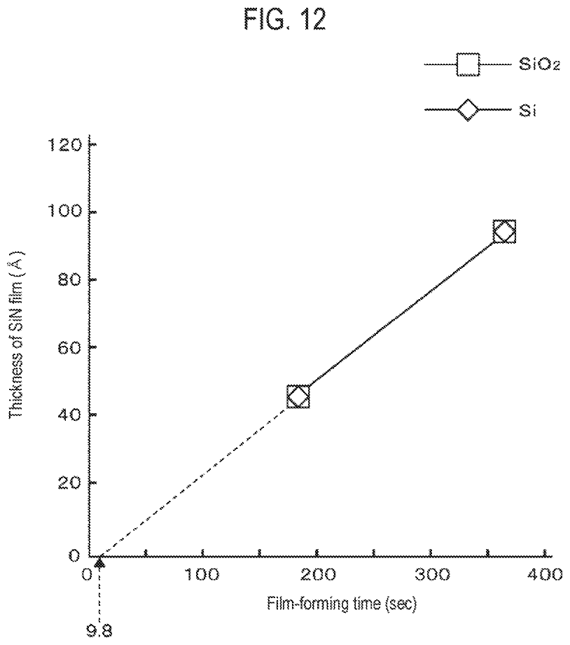

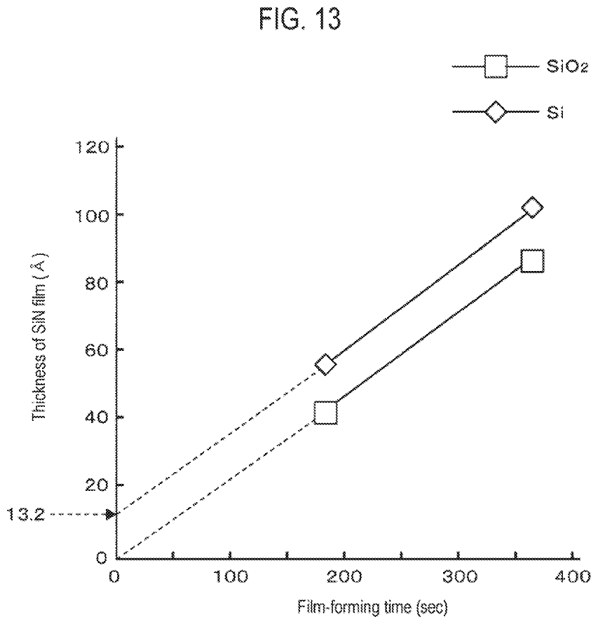

The graph of FIG. 12 shows the result of Evaluation Test 1, and the graph of FIG. 13 shows the result of Comparative Test 1. In each graph, the horizontal axis represents a film forming time of the SiN film 68 in step S3 (unit: second), and the vertical axis represents a film thickness (angstrom) of the SiN film 68. In each graph, the measured thicknesses of the SiN films 68 are plotted, and a solid line connecting respective points plotted for the bare wafers and a solid line connecting respective points plotted for the SiO₂ wafers are shown. Further, in the graphs, an extension line extending each of the above-described solid lines to a position where the film forming time on the horizontal axis is 0 seconds or to a position where the thickness of the SiN film 68 on the vertical axis is 0 angstrom is shown by a dotted line. In addition, the incubation time with respect to a film was defined as the time until film formation starts when a SiN film is formed to be in direct contact with the film. However, regardless of the definition, in this evaluation test, the incubation time is set to the film forming time when the film thickness is 0 angstrom, as seen from the extension of the dotted line.

In Evaluation Test 1, in both cases of setting the film forming time of the SiN film 68 to 180 seconds and 360 seconds, almost no difference was observed in the thicknesses of the SiN film 68 between the SiO₂ wafers and the bare wafers. Further, the incubation time with respect to the SiO₂ wafers was 9.8 seconds, and the incubation time with respect to the bare wafers was also about 9.8 seconds. In addition, when the film forming time was 9.8 seconds, a difference in the film thickness (a thickness of the SiN film 68 formed on the bare wafers—a thickness of the SiN film 68 formed on the SiO₂ wafers) was −0.6 angstrom, i.e., approximately 0 angstrom. That is, it was confirmed that, in both cases of the SiO₂ wafers or the bare wafers, the formation of the SiN film 68 started when about 9.8 seconds elapsed after the start of step S3.

In contrast, in Comparative Test 1, in both cases of setting the film forming time of the SiN film 68 to 180 seconds and 360 seconds, a relatively large difference in the thicknesses of the SiN film 68 was observed between the SiO₂ wafers and the bare wafers. In addition, the incubation time with respect to the SiO₂ wafers was about 0 seconds, but with respect to the bare wafers, the thickness of the SiN film 68 was 13.2 angstrom when the film forming time was 0 seconds. The reason that the SiN film 68 was already formed at the film forming time of 0 seconds can be considered to be that the surfaces of the bare wafers were nitrided to form SiN by being exposed to the plasma of the N₂ gas. From the results of Evaluation Test 1 and Comparative Test 1 as described above, it was confirmed that it is possible to make the film thickness uniform between the Si film and the SiO₂ film according to the method described in the above-described embodiments.

### (Evaluation Test 2)

As Evaluation Test 2, the processes including the above-described steps S1 to S3 were performed on the bare wafers and the SiO₂ wafers as in Evaluation Test 1, and the thicknesses of the SiN films 68 were obtained. Then, as described with reference to FIG. 12, the thicknesses of SiN films 68 were plotted on a graph, and the incubation time was obtained from the extension of the straight line connecting the plotted points. In addition, a difference in film thickness (the thickness of the SiN films 68 on the bare wafers—the thickness of the SiN films 68 on the SiO₂ wafers) was calculated.

As Comparative Test 2-1, the bare wafers and the SiO₂ wafers were processed by performing only step S3 without performing the preprocessing of steps S1 and S2. As Comparative Test 2-2, without performing steps S1 and S2, step S3 was performed after supplying an HCD gas from the shower head 2 to the rotating bare wafers and SiO₂ wafers. As Comparative Test 2-3, without performing steps S1 and S2, plasma of a H₂ gas was formed in the plasma forming regions R1 to R3 to expose the rotating bare wafers and SiO₂ wafers to the plasma of the H₂ gas, and then step S3 was performed. Except for the above-described differences, the same processes in Evaluation Test 2 were performed in Comparative Tests 2-1 to 2-3. As in Evaluation Test 2, the incubation time was obtained and the difference in film thickness was calculated with respect to the wafers processed in the Comparative Tests 2-1 to 2-3.

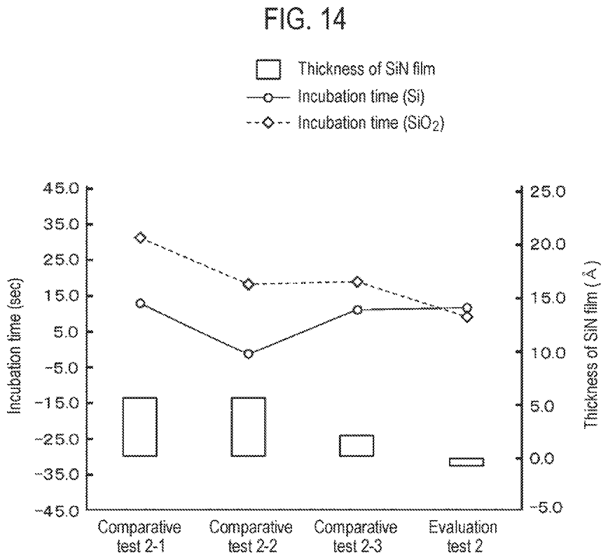

The graph of FIG. 14 shows the results of Evaluation Test 2 and Comparative Tests 2-1 to 2-3. In this graph, the obtained incubation times (unit: seconds) are plotted, and points plotted for the bare wafers are connected and shown by a solid line while points plotted for the SiO₂ wafers are connected and shown by a dotted line. In addition, bar graphs show the differences in film thickness (unit: angstrom).

As shown in the graph, in Comparative Tests 2-1 to 2-3, the difference in incubation time and the difference in film thickness between the Si wafers and the SiO₂ wafers were larger than those in Evaluation Test 2. Therefore, it is considered that the processes described in the above embodiments are effective for reducing the difference in incubation time and the difference in film thickness. In addition, from the results of Evaluation Test 2 and Comparative Tests 2-2 and 2-3, it is considered that a sufficient effect cannot be obtained when only one of supplying an HCD and supplying plasma of a H₂ gas is performed, and that it is necessary to perform both of these processes as in step S1 of the embodiments in order to obtain a sufficient effect.

According to the present disclosure, in forming a silicon nitride film on a substrate having a first film and a second film exposed on the surface thereof, it is possible to make a film thickness of the silicon nitride film formed on the first film and the second film uniform.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method of forming a silicon nitride film on a substrate including a first film and a second film formed on a surface of the substrate, wherein the first film and the second film have different required incubation times until growth of the silicon nitride film starts when a source gas containing silicon and a first nitriding gas for nitriding the silicon are supplied, the method comprising:
supplying a plasmarized hydrogen gas to the substrate;
supplying a processing gas formed of silicon halide to the substrate;
forming a thin layer of silicon covering the first film and the second film by alternately and repeatedly performing the supplying the plasmarized hydrogen gas and the supplying the processing gas;
forming a thin layer of silicon nitride by supplying a second nitriding gas for nitriding the thin layer of silicon to the substrate; and
forming the silicon nitride film on the thin layer of the silicon nitride by supplying the source gas and the first nitriding gas to the substrate.

2. The film forming method of claim 1, wherein the silicon halide forming the processing gas is silicon chloride.

3. The film forming method of claim 2, wherein the silicon chloride is hexachlorodisilane.

4. The film forming method of claim 3, wherein the second nitriding gas is a plasmarized ammonia gas.

5. The film forming method of claim 4, wherein the first film is a silicon film, and the second film includes a silicon oxide film or a metal film.

6. The film forming method of claim 5, wherein the second film includes the metal film, and the metal film is a tungsten film.

7. The film forming method of claim 1, wherein the second nitriding gas is a plasmarized ammonia gas.

8. The film forming method of claim 1, wherein the first film is a silicon film, and the second film includes a silicon oxide film or a metal film.

9. A film forming apparatus for forming a silicon nitride film on a substrate including a first film and a second film on a surface of the substrate, wherein the first film and the second film have different required incubation times until growth of the silicon nitride film starts when a source gas containing silicon and a first nitriding gas for nitriding the silicon are supplied, the apparatus comprising:
a rotary table configured to place the substrate on the rotary table and cause the substrate to rotate;
a hydrogen gas supplier configured to supply a plasmarized hydrogen gas on the rotary table;
a processing gas supplier configured to supply a processing gas formed of silicon halide on the rotary table;
a nitriding gas supplier configured to supply the first nitriding gas and a second nitriding gas on the rotary table;
a source gas supplier configured to supply the source gas on the rotary table; and
a controller configured to perform control of:
forming a thin layer of silicon covering the first film and the second film by alternately and repeatedly supplying the plasmarized hydrogen gas and the processing gas to the rotating substrate;
forming a thin layer of silicon nitride by nitriding the thin layer of silicon by supplying the second nitriding gas to the rotating substrate; and
forming the silicon nitride film on the thin layer of the silicon nitride by alternately and repeatedly supplying the source gas and the first nitriding gas to the rotating substrate.

10. The film forming apparatus of claim 9, further comprising:
a first gas supplier configured to supply a first gas to a first region on the rotary table; and
a second gas supplier configured to supply a second gas to a second region on the rotary table and simultaneously plasmarize the second gas, the second region being spaced apart from the first region in a rotation direction of the rotary table and having an atmosphere separated from an atmosphere of the first region,
wherein the first gas supplier includes the source gas supplier and the processing gas supplier, and
wherein the first nitriding gas and the second nitriding gas are plasmarized nitriding gases, and the second gas supplier includes the nitriding gas supplier and the hydrogen gas supplier.
